(19) United States
(12) Patent Application Publication
(10) Pub. No.: US 2024/0312856 A1
(43) Pub. Date: Sep. 19, 2024

(54) ELECTRONIC COMPONENT PACKAGE, CIRCUIT MODULE AND METHOD FOR PRODUCING ELECTRONIC COMPONENT PACKAGE

(71) Applicant: Murata Manufacturing Co., Ltd., Kyoto (JP)

(72) Inventors: Hiroki YOSHIMORI, Kyoto (JP); Tsuyoshi TAKAKURA, Kyoto (JP); Daisuke KINO, Kyoto (JP); Hideo NAKAGOSHI, Kyoto (JP); Takamitsu NAKAMURA, Kyoto (JP)

(21) Appl. No.: 18/674,230

(22) Filed: May 24, 2024

Related U.S. Application Data
(63) Continuation of application No. PCT/JP2022/036906, filed on Oct. 3, 2022.

(30) Foreign Application Priority Data
Nov. 26, 2021 (JP) 2021-192398

(51) Int. Cl. H01L 23/31; H01L 21/56; H01L 23/00; H01L 23/498; H01L 25/16

(52) U.S. Cl. CPC H01L 23/3107; H01L 21/565; H01L 24/16; H01L 24/81; H01L 25/16; H01L 23/49822; H01L 2224/16013; H01L 2224/16014; H01L 2224/16227; H01L 2224/16238; H01L 2224/81005; H01L 2224/81815; H01L 2924/3512

(57) ABSTRACT

An electronic component package includes an electronic component and a sealing resin sealing the electronic component. In the electronic component package, one of main surfaces of the sealing resin defines a mounting surface used for mounting the electronic component package on a different substrate, and in a view of the mounting surface of the sealing resin, a land electrically connected to an electrode of an electronic component and a conductor made of solder or an alloy phase between the solder and another metal and surrounding at least a portion of an outer circumference of the land are exposed on the mounting surface.

### CROSS REFERENCE TO RELATED APPLICATION

This is a continuation of International Application No. PCT/JP2022/036906 filed on Oct. 3, 2022 which claims priority from Japanese Patent Application No. 2021-192398 filed on Nov. 26, 2021. The contents of these applications are incorporated herein by reference in their entireties.

### BACKGROUND OF THE DISCLOSURE

### Field of the Disclosure

The present disclosure relates to an electronic component package, a circuit module, and a method of producing the electronic component package.

### Description of the Related Art

Electronic component packages including an electronic component sealed with a resin and not including a support substrate have been known conventionally. Such an electronic component package is mounted on a different substrate and used as, for example, a circuit module for high frequency. Patent Literature 1 discloses an electronic component package used for such an application and a circuit module.
Patent Literature 1: WO 2018/084143

### BRIEF SUMMARY OF THE DISCLOSURE

The electronic component package disclosed in Patent Literature 1 includes exposure parts where conductive members are exposed on a mounting surface of a resin sealing member. According to the disclosure, the conductive members are formed of solder bumps, and the exposure parts are alloy layers made of Sn and Cu.

The electronic component package disclosed in Patent Literature 1 is mounted on a different substrate provided with solder bumps and is used as a circuit module. Commonly, reflow is performed multiple times on an electronic component package. When an electronic component package mounted on a different substrate is reflowed again to bond other components and the like thereto, remelting of solder bumps, if occurs, may cause short-circuit failure due to flowing of the solder to adjacent terminals. In the electronic component package disclosed in Patent Literature 1, a high-melting point alloy phase made of Sn and Cu is formed in each exposure part. This alloy phase diffuses and disappears when the electronic component package is mounted on a different substrate. Thus, the electronic component package according to Patent Literature 1, when reflowed again, may cause short-circuit failure due to remelting of the solder bumps.

The present disclosure was made to solve the above issue and aims to provide an electronic component package capable of maintaining the bonding reliability even when the electronic component package is reflowed again after mounted on a different substrate.

An electronic component package of the present disclosure includes: an electronic component; a sealing resin sealing the electronic component, wherein one of main surfaces of the sealing resin defines a mounting surface used for mounting the electronic component package on a different substrate, and in a view of the mounting surface of the sealing resin, a land electrically connected to an electrode of the electronic component and a conductor made of solder or an alloy phase between the solder and another metal and surrounding at least a portion of an outer circumference of the land are exposed on the mounting surface.

A circuit module of the present disclosure includes the electronic component package of the present disclosure and a substrate on which the electronic component package is mounted.

A method of producing the electronic component package of the present disclosure includes: preparing a dummy substrate including a first surface on which a land is formed; supplying solder to the dummy substrate so as to surround at least a portion of an outer circumference of the land; mounting an electronic component to the dummy substrate by bringing the electronic component into contact with the solder; sealing the electronic component with a sealing resin; and removing the dummy substrate by grinding a second surface of the dummy substrate on which the land is not formed so as to expose the land and a conductor made of solder or an alloy phase between the solder and another metal and surrounding at least a portion of an outer circumference of the land.

According to the present disclosure, since a material that forms a high-melting point alloy phase is supplied from the land, a high-melting point alloy phase at a bonding portion of a solder bump can be maintained even after the electronic component package is mounted on a different substrate. Reflowing will not cause either remelting or short-circuit failure. Thus, an electronic component package can be provided which is capable of maintaining the bonding reliability even when the electronic component package is reflowed again after being mounted on a different substrate.

### BRIEF DESCRIPTION OF THE SEVERAL VIEWS OF THE DRAWINGS

FIG. 1 is a schematic cross-sectional view of an example of an electronic component package.

FIG. 2 is a schematic plan view of a land and a conductor exposed on a mounting surface of the electronic component package shown in FIG. 1.

FIG. 3 is an enlarged cross-sectional view of a portion described as a region A of the electronic component package shown in FIG. 1.

FIG. 4 is a schematic cross-sectional view of the electronic component package to depict the overall step of mounting the electronic component package on a substrate to provide a circuit module.

FIG. 5A is a schematic cross-sectional view of the land and the conductor to depict a mounting process of the electronic component package on a substrate.

FIG. 5B is a schematic cross-sectional view of the land and the conductor to depict the mounting process of the electronic component package on the substrate.

FIG. 5C is a schematic cross-sectional view of the land and the conductor to depict the mounting process of the electronic component package on the substrate.

FIG. 5D is a schematic cross-sectional view of the land and the conductor to depict the mounting process of the electronic component package on the substrate.

FIG. 6 is a schematic cross-sectional view of an example of the circuit module.

FIG. 7A is a schematic step diagram of an example of a method of producing the electronic component package.

FIG. 7B is a schematic step diagram of an example of the method of producing the electronic component package.

FIG. 7C is a schematic step diagram of an example of the method of producing the electronic component package.

FIG. 7D is a schematic step diagram of an example of the method of producing the electronic component package.

FIG. 7E is a schematic step diagram of an example of the method of producing the electronic component package.

FIG. 8 is a schematic plan view of an example of an embodiment in which a conductor surrounds a portion of an outer circumference of a land.

FIG. 9 is a schematic plan view of an embodiment in which the conductor connects between multiple lands on the mounting surface.

FIG. 10 is a schematic plan view of a modified example of the embodiment in which the conductor connects between multiple lands on the mounting surface.

### DETAILED DESCRIPTION OF THE DISCLOSURE

Hereinafter, the electronic component package, the circuit module, and the method of producing the electronic component package of the present disclosure are described.

The present disclosure is not limited to the following preferred embodiments and may be suitably modified without departing from the gist of the present disclosure. Combinations of two or more preferred features described in the following preferred embodiments are also within the scope of the present disclosure.

### First Embodiment

An electronic component package of a first embodiment is described in which a conductor surrounds an outer circumference of a land in a view of a mounting surface of a sealing resin.

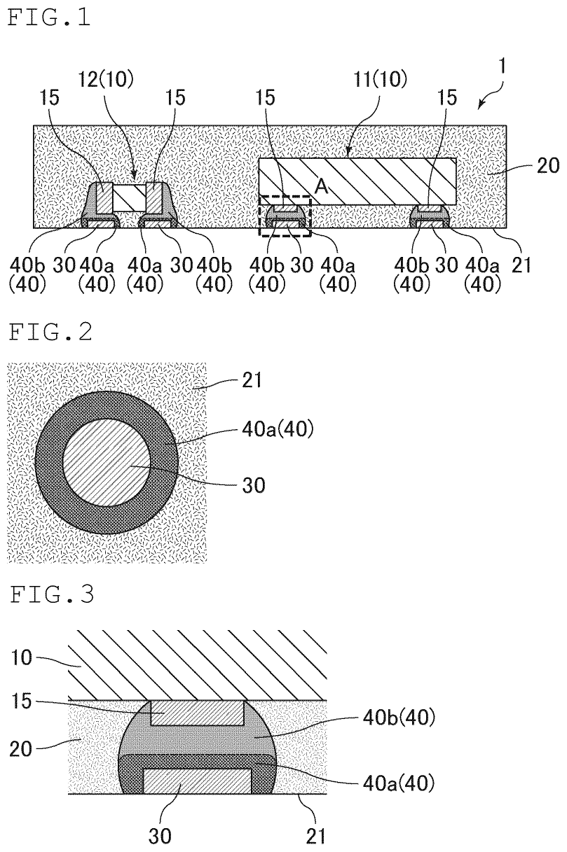

FIG. 1 is a schematic cross-sectional view of an example of the electronic component package. FIG. 2 is a schematic plan view of the land and the conductor exposed on the mounting surface of the electronic component package shown in FIG. 1.

An electronic component package 1 shown in FIG. 1 includes electronic components 10 and a sealing resin 20 sealing the electronic components 10. FIG. 1 shows a semiconductor component 11 and a multilayer ceramic electronic component 12 as the electronic components 10.

The electronic component is not limited and may be a chip component. Examples of the chip component include multilayer ceramic electronic components such as semiconductor components (e.g., ICs and memories), LC composite components (e.g., multilayer filters), multilayer ceramic capacitors, and multilayer inductors.

An insulation material such as an epoxy resin can be used as the sealing resin. The composition thereof is not limited.

A mounting surface 21, which defines one of main surfaces of the sealing resin 20, is a surface used for mounting the electronic component package 1 on a different substrate.

Lands 30 and conductors 40 are exposed on the mounting surface 21. The lands 30 are electrically connected to electrodes 15 of the electronic components 10. The lands 30 may be electrically connected to the electrodes 15 of the electronic components 10 via a direct contact with the electrodes 15 of the electronic components 10 or may be electrically connected to the electrodes 15 of the electronic components 10 via other conducting materials such as the conductors 40. In either case, the electrode 15 of each electronic component 10 is electrically drawn to where the land 30 is flush with the mounting surface 21.

FIG. 2 shows a positional relationship between the land 30 and the conductor 40 in a view of the mounting surface 21 of the sealing resin 20. The conductor 40 surrounds the outer circumference of the land 30.

FIG. 2 shows an embodiment in which the conductor 40 surrounds the entire outer circumference of the land 30. In this case, the conductor surrounds 100% of the outer circumference length of the land.

FIG. 3 is an enlarged cross-sectional view of a portion described as a region A of the electronic component package shown in FIG. 1.

A preferred material of the land 30 is copper. Its surface is not necessarily Ni—Au plated. The electronic component package of the present disclosure has excellent mountability on a different substrate even when the lands are not Ni—Au plated on their surfaces. A description regarding the effect will be given later.

The lands may be Ni—Au plated on their surfaces.

The lands 30 and the conductors 40 are both exposed on the mounting surface 21. Only the conductors will be exposed in the case of bonding only using solder bumps without using the lands. In such a case, when the conductors are cracked, the cracks may keep propagating. However, when the lands 30 are present, propagation of the cracks in the conductors 40 can be stopped by the lands 30, which can improve the bonding stability between the electronic component package and a different substrate.

The conductors 40 are made of solder or an alloy of solder and another metal. Herein, the composition of the solder is not limited. Any solder used for bonding electronic components can be used. For example, Sn—Ag—Cu-based Pb-free solder can be used.

When the conductors are made of an alloy of solder and another metal, the alloy can be of copper of the lands and solder. The alloy of copper and solder forms an alloy phase having a higher melting point than the solder. Herein, the alloy phase from the alloy of the metal of the lands and the solder is also referred to as a “first high-melting point alloy phase”.

FIG. 3 shows that the conductor 40 is in the form of a high-melting point alloy phase 40a around the land 30 and is in the form of solder 40b away from the land 30.

In other words, the first high-melting point alloy phase 40a as the conductor 40 may cover at least a portion of the outer circumference of the land 30 on the mounting surface.

The following describes steps of mounting the electronic component package of the present disclosure on a substrate to provide a circuit module.

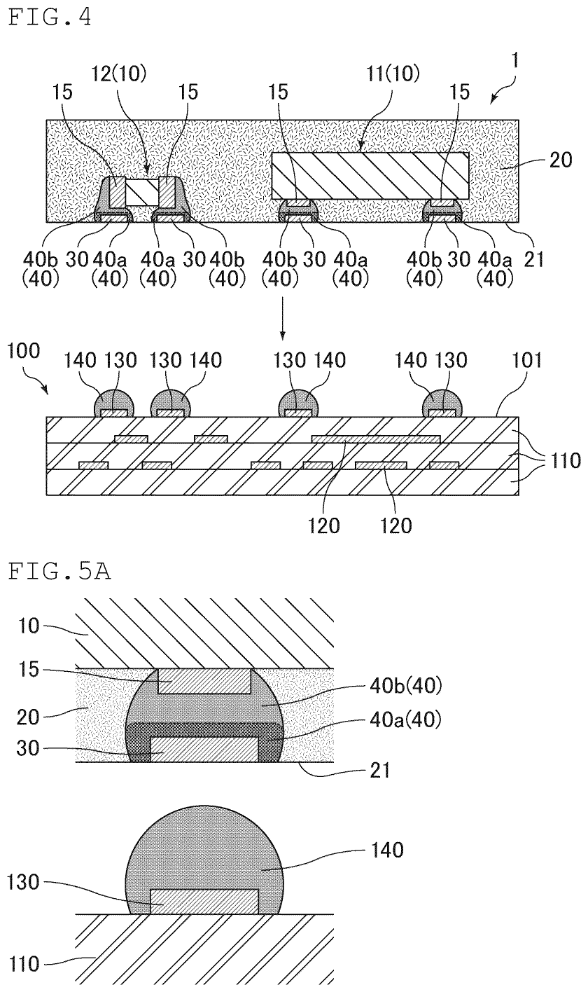

FIG. 4 is a schematic cross-sectional view of the electronic component package to depict the overall step of mounting the electronic component package on a substrate to provide a circuit module.

The electronic component package 1 shown in FIG. 4 is the electronic component package of the present disclosure described above.

FIG. 4 shows a substrate 100. The substrate 100 is a multilayer substrate and includes multiple insulation layers 110 and wires 120 in the insulation layers 110. Substrate lands 130 and solder (hereinafter referred to as “substrate solder 140”) covering the substrate lands 130 are on a main surface 101 of the substrate 100 on which the electronic component package 1 is to be mounted.

Although FIG. 4 clearly shows the borderlines of each layer of the substrate 100, the borderlines of each layer cannot be distinguished in the case of a low temperature co-fired ceramic substrate or the like.

The substrate 100 is not limited and may be, for example, a ceramic substrate such as a low temperature co-fired ceramic substrate (LTCC substrate) or a resin substrate such as a glass epoxy substrate, a polyimide substrate, or a liquid crystal polymer substrate.

The lands 30 of the electronic component package 1 are brought into contact with the substrate solder 140 covering the substrate lands 130 on the substrate 100, followed by heating to melt the substrate solder 140, whereby the electronic component package 1 is mounted on the substrate 100 to provide a circuit module.

When mounting the electronic component package 1 on the substrate 100, the lands 30 of the electronic component package 1 are placed in alignment with the positions of the substrate lands 130 on the substrate 100, followed by heating in a reflow furnace. At this point, the substrate solder 140 covering the substrate lands 130 is melted and bonded with the lands 30. This process is described with reference to the drawings.

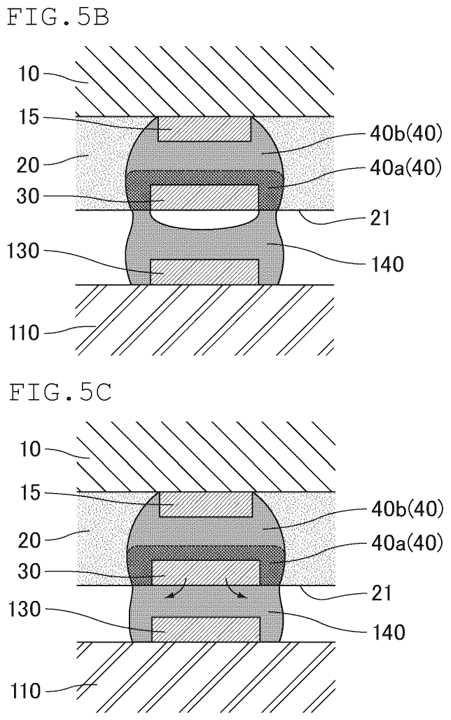

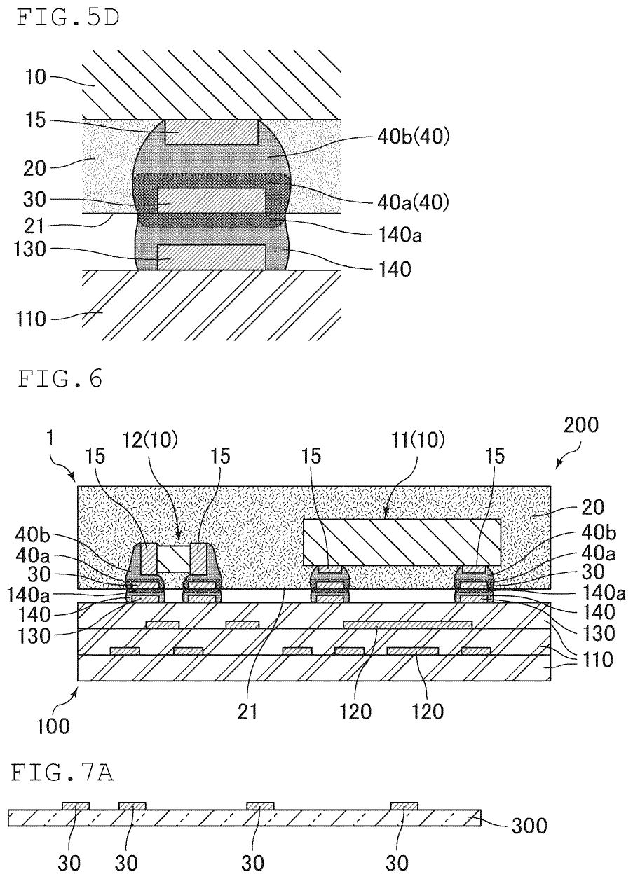

FIGS. 5A, 5B, 5C, and 5D are each a schematic cross-sectional view of the land and the conductor to depict a mounting process of the electronic component package on a substrate.

FIG. 5A shows a state before contact is made between the substrate solder 140 covering the substrate land 130 and the land 30 of the electronic component package 1.

FIG. 5B shows a state where the substrate solder 140 is melted, and the melted substrate solder 140 is in contact with the conductor 40 of the electronic component package 1.

FIG. 5B shows a state where the melted substrate solder 140 wets and comes into contact with the conductor 40 exposed on the mounting surface 21. The conductor 40 is made of solder or an alloy of solder and another metal. Thus, the conductor 40 has good wettability to the melted solder, and the melted substrate solder 140 wets the conductor 40 and makes a good contact therewith.

Then, the substrate solder 140 that came into contact with the conductor 40 further wet-spreads, and the substrate solder 140 can also wet and come into contact with the land 30.

The surfaces of the lands made of copper have poor wettability to melted solder, so that the surfaces of the lands are Ni—Au plated to improve the solder wettability. In contrast, in the electronic component package of the present disclosure, each conductor covers at least a portion of the outer circumference of each land on the mounting surface. Thus, the melted solder can first wet the conductors having good wettability to the melted solder, and the solder that came into contact with the conductors spreads, whereby the solder can wet-spread on the surfaces of the lands even when the surfaces of the lands are not Ni—Au plated. Thus, the electronic component package of the present disclosure exhibits excellent mountability when it is mounted on a different substrate.

FIG. 5C shows a state where the substrate solder 140 is in contact with the land 30. When the melted substrate solder 140 is in contact with the land 30, the metal (usually, copper) of the land 30 forms an alloy with the substrate solder 140. FIG. 5C schematically shows, with arrows, a state where the metal (usually, copper) of the land 30 is seeping into the substrate solder 140.

FIG. 5D shows a state where a second high-melting point alloy phase 140a is formed at a portion where the metal (usually, copper) of the land 30 seeped into the substrate solder 140.

Herein, the alloy phase from the alloy of the metal of the lands and the substrate solder is also referred to as the “second high-melting point alloy phase”. When the metal of each land 30 is copper, the alloy of copper and solder forms an alloy phase having a higher melting point than the solder.

The first high-melting point alloy phase and the second high-melting point alloy phase may have the same composition.

In the electronic component package of the present disclosure, a substantially hemispheric bump can be formed on each land by suitably adjusting the amount of solder to be supplied to the land. Likewise, the degree of constriction at the interface between the mounting surface of the electronic component package and the substrate solder can be reduced by suitably adjusting the amount of solder to be supplied when mounting the electronic component package on a different substrate. This can prevent a crack from occurring at the constriction as a starting point.

The electronic component package is mounted on the substrate by the above steps, whereby the circuit module of the present disclosure can be obtained.

The circuit module of the present disclosure includes the electronic component package of the present disclosure and a substrate on which the electronic component package is mounted.

FIG. 6 is a schematic cross-sectional view of an example of the circuit module.

A circuit module 200 includes the electronic component package 1 and the substrate 100 on which the electronic component package 1 is mounted. In the circuit module 200, the lands 30 of the electronic component package 1 are not Ni—Au plated on their surfaces, but a good connection is established between each land 30 and the substrate solder 140 of the substrate 100.

Subsequently, a method of producing the electronic component package of the present disclosure is described.

The method of producing the electronic component package of the present disclosure includes: preparing a dummy substrate including a first surface on which a land is formed; supplying solder to the dummy substrate so as to surround at least a portion of an outer circumference of the land; mounting an electronic component to the dummy substrate by bringing the electronic component into contact with the solder; sealing the electronic component with a sealing resin; and removing the dummy substrate by grinding a second surface of the dummy substrate on which the land is not formed so as to expose the land and a conductor made of solder or an alloy phase between the solder and another metal and surrounding at least a portion of an outer circumference of the land.

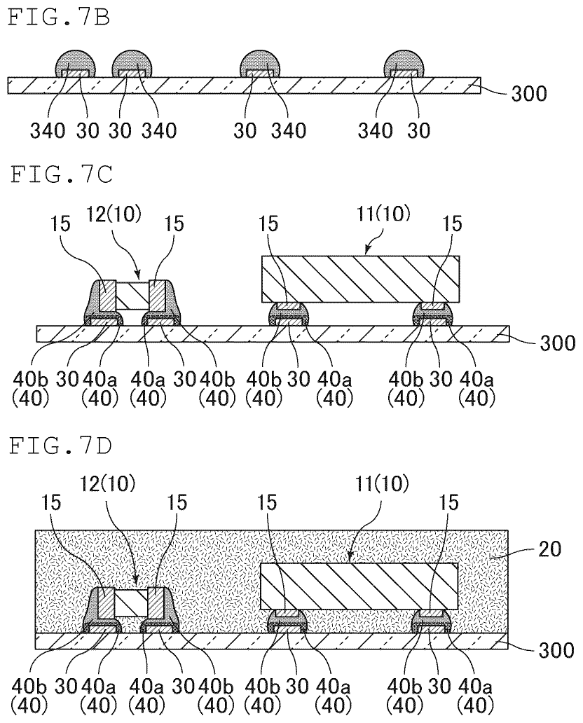

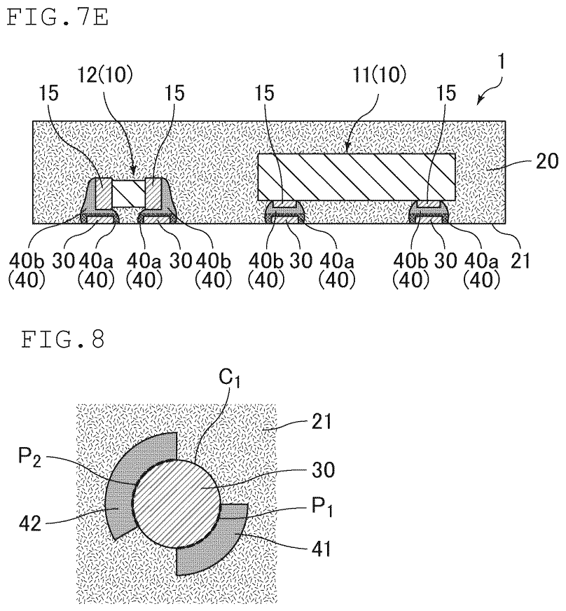

FIGS. 7A, 7B, 7C, 7D, and 7E are each a schematic step diagram of an example of the method of producing the electronic component package.

First, as shown in FIG. 7A, a dummy substrate 300 with the lands 30 formed thereon is prepared.

The dummy substrate 300 is not limited, and a resin substrate such as a glass epoxy substrate can be used.

A thinner dummy substrate is better because the dummy substrate is to be removed by grinding. Preferably, the thickness is 40 μm or more and 300 μm or less.

The lands 30 can be formed at predetermined positions by disposing a metal layer on the dummy substrate 300 by metal plating, attaching metal foil, or applying a conductive paste thereto and etching the metal layer for patterning. The lands 30 may be formed by disposing metal layers made of a conductive paste at predetermined positions by inkjet printing or screen printing.

The lands 30 may also be formed at predetermined positions by preparing copper foil with a resin and etching the copper foil for patterning.

To ensure a sufficient land thickness after grinding the dummy substrate 300, preferably, the thickness of each land 30 to be formed in this step is 20 μm or more.

Subsequently, as shown in FIG. 7B, solder 340 is applied to the dummy substrate 300 such that the solder 340 covers at least a portion of the outer circumference of each land 30.

The solder 340 can be applied by a method such as screen printing or inkjet printing using a solder paste in alignment with the positions of the lands 30. In the case of screen printing, the metal mask opening size is made larger than the size of the land, whereby the solder can be applied to surround the outer circumference of each land.

Subsequently, as shown in FIG. 7C, electrodes of the electronic components 10 (the semiconductor component 11 and the multilayer ceramic electronic component 12) are placed in alignment with the positions of the solder 340, and the solder 340 is brought into contact with the electronic components 10, followed by heating in a reflow furnace, whereby the electronic components 10 are mounted on the dummy substrate 300.

In this step, the metal (usually, copper) of each land 30 reacts with the solder 340 to form the first high-melting point alloy phase 40a. The solder 340 away from the lands 30 remains as is (which is shown as the solder 40b in FIG. 7C).

The above step is followed by sealing the electronic components 10 with the sealing resin 20 as shown in FIG. 7D. The sealing with the sealing resin can be performed by a method such as a resin coating method using a liquid resin, a resin forming method using a resin sheet, a transfer molding method, or a compression molding method. The resin is cured after the sealing.

Further, a surface of the dummy substrate 300 on which no lands 30 are formed in FIG. 7D (i.e., the surface on which no electronic components 10 are mounted) is ground, whereby the dummy substrate 300 is removed.

FIG. 7E shows the electronic component package 1 after removal of the dummy substrate 300.

Removing the dummy substrate 300 causes exposure of the lands 30 and the conductors 40 (the first high-melting point alloy phase 40a in FIG. 7E) each made of solder or an alloy phase between the solder and another metal and surrounding at least a portion of the outer circumference of each land 30. The dummy substrate 300 is ground until the lands 30 and the conductors 40 are exposed and to a degree that the lands 30 are not entirely ground.

The dummy substrate can be ground by a method such as wet blasting, machining, or laser processing.

The electronic component package of the present disclosure can be produced by the above steps.

### Modified Example of First Embodiment

Hereinafter, a modified example of the electronic component package according to the first embodiment is described.

In the electronic component package of the present disclosure, it suffices as long as the conductor surrounds at least a portion of the outer circumference of each land. For example, preferably, the conductor surrounds 50% or more and 100% or less of the outer circumference length of each land on the mounting surface.

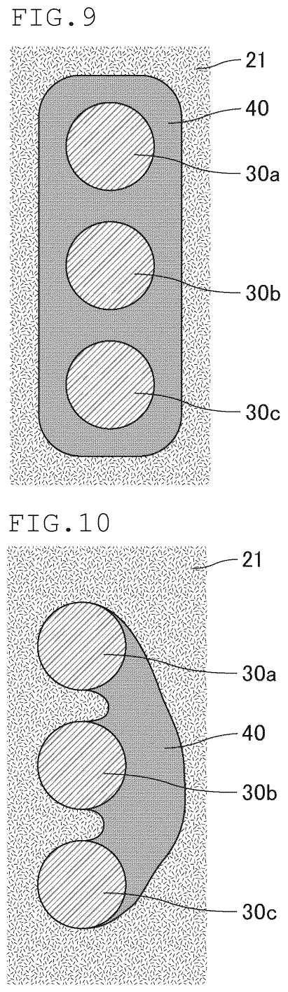

FIG. 8 is a schematic plan view of an example of an embodiment in which the conductor surrounds a portion of the outer circumference of the land.

Even in the case where the conductor surrounds a portion of the outer circumference of the land as in the embodiment shown in FIG. 8, the substrate solder that came into contact with the conductor wet-spreads from the conductor as a starting point, and the substrate solder can also wet and come into contact with the land.

However, when the conductor surrounds less than 50% of the outer circumference length of the land, the substrate solder may not make sufficient contact with the land due to a shortage in the amount of the substrate solder that first comes into contact with the conductor.

In the embodiment shown in FIG. 8, the length of the circumference (outer circumference) of the land 30 is defined as the length C1. The conductor is divided into two portions (a conductor 41 and a conductor 42). The length of the line corresponding to the conductor 41 and the length of the line corresponding to the conductor 42 on the outer circumference of the land 30 are defined as P1 and P2, respectively. Assuming that the total length of P1 and P2 is the length of the portions of the outer circumference of the land surrounded by the conductors, the ratio of the length (P1+P2) to the length C1 is expressed as a percentage, and the ratio is defined as the total length of the portions of the outer circumference of the land surrounded by the conductors.

FIG. 8 shows the embodiment in which the conductor surrounds about 60% of the outer circumference length of the land. The embodiment shown in FIG. 2 is one in which the conductor surrounds 100% of the outer circumference length of the land.

In the electronic component package of the present disclosure, on the mounting surface, preferably, the area of each conductor surrounding the outer circumference of the land is 50% or more and 500% or less of the area of the land.

Examples of cases where the area of the conductor is too small relative to the area of the land include a case where the conductor has a ring shape with a very narrow width. In such a case, when the area of the conductor surrounding the outer circumference of the land is less than 50% of the area of the land, the substrate solder may not make sufficient contact with the land due to a shortage in the amount of the substrate solder that first comes into contact with the conductor. From such a perspective, preferably, each conductor has an area that allows a certain amount of the substrate solder to be in contact therewith. Preferably, the area of the conductor surrounding the outer circumference of the land is 500% or less of the area of the land, because even when the area of the conduct is excessively large, attachment of an excessive amount of the substrate solder is unnecessary.

When the conductor is divided into multiple portions as in the embodiment shown in FIG. 8, the areas of the portions of the conductor are added to consider the area ratio of the conductor to the land.

### Second Embodiment

An electronic component package of a second embodiment is described in which the land includes multiple lands disposed on the mounting surface, and a portion of the conductor connects between the multiple lands.

FIG. 9 is a schematic plan view of an embodiment in which the conductor connects between multiple lands on the mounting surface.

In the embodiment shown in FIG. 9, multiple lands including lands 30a, 30b, and 30c are exposed on the mounting surface 21. The conductor 40 connects between these multiple lands.

The conductor surrounds at least a portion of the outer circumference of each land and connects between the lands.

Preferably, the conductor surrounds 50% or more and 100% or less of the outer circumference of each land. This means that every land is surrounded by a certain amount of the conductor.

In the embodiment shown in FIG. 9, the conductor surrounds 100% of the outer circumference of each land.

Preferably, the area of the conductor surrounding the outer circumferences of the multiple lands is 50% or more and 500% or less of the total area of the multiple lands. In this case, the percentage is calculated from the ratio of the total area of the conductor surrounding the multiple lands to the total area of the multiple lands.

FIG. 10 is a schematic plan view of a modified example of the embodiment in which the conductor connects between multiple lands on the mounting surface.

In the embodiment shown in FIG. 10, multiple lands including the lands 30a, 30b, and 30c are exposed on the mounting surface 21. The conductor 40 connects between these multiple lands.

The conductor 40 surrounds the right side of each of the lands 30a, 30b, and 30c. However, the conductor 40 at the left, upper, and lower side of each land is not exposed on the mounting surface 21.

When forming a conductor, there may be a case where the formation position of the conductor is lopsided as shown in FIG. 10 due to the shape of an electrode of an electronic component, solder wettability, and surface tension. Preferably, the formation position of the conductor is not lopsided. Yet, even if it is the case, since the conductor surrounds at least a portion of the outer circumference of each land on the mounting surface, the substrate solder that came into contact with the conductor wet-spreads from the conductor as a starting point, and the substrate solder can also wet and come into contact with the land.

Yet, as shown in FIG. 9, preferably, the formation position of the conductor 40 is not lopsided with respect to any of the positions of the lands 30a, 30b, and 30c.
1 electronic component package
10 electronic component
11 semiconductor component
12 multilayer ceramic electronic component
15 electrode of electronic component
20 sealing resin
21 mounting surface
30, 30a, 30b, 30c land
40, 41, 42 conductor
40a first high-melting point alloy phase
40b solder
100 substrate
101 main surface of substrate
110 insulation layer
120 wire
130 substrate land
140 substrate solder
140a second high-melting point alloy phase
200 circuit module
300 dummy substrate
340 solder (solder supplied to dummy substrate)

1. An electronic component package, comprising:
an electronic component; and
a sealing resin sealing the electronic component,
wherein one of main surfaces of the sealing resin defines a mounting surface for mounting the electronic component package on a different substrate, and
in a view of the mounting surface of the sealing resin, a land electrically connected to an electrode of the electronic component and a conductor comprising solder or an alloy phase between the solder and another metal and surrounding at least a portion of an outer circumference of the land are exposed on the mounting surface.

2. The electronic component package according to claim 1,
wherein on the mounting surface, the conductor surrounds 50% or more and 100% or less of the outer circumference length of the land.

3. The electronic component package according to claim 1,
wherein on the mounting surface, an area of the conductor surrounding the outer circumference of the land is 50% or more and 500% or less of an area of the land.

4. The electronic component package according to claim 1,
wherein the land includes multiple lands disposed on the mounting surface, and a portion of the conductor connects between the multiple lands.

5. A circuit module comprising:
the electronic component package according to claim 1; and
a substrate on which the electronic component package is mounted.

6. A method of producing the electronic component package according to claim 1, the method comprising:
preparing a dummy substrate including a first surface on which a land is formed;
supplying solder to the dummy substrate so as to surround at least a portion of an outer circumference of the land;
mounting an electronic component to the dummy substrate by bringing the electronic component into contact with the solder;
sealing the electronic component with a sealing resin; and
removing the dummy substrate by grinding a second surface of the dummy substrate on which the land is not formed so as to expose the land and a conductor comprising solder or an alloy phase between the solder and another metal and surrounding at least a portion of an outer circumference of the land.

7. The electronic component package according to claim 2,
wherein on the mounting surface, an area of the conductor surrounding the outer circumference of the land is 50% or more and 500% or less of an area of the land.

8. The electronic component package according to claim 2,
wherein the land includes multiple lands disposed on the mounting surface, and a portion of the conductor connects between the multiple lands.

9. The electronic component package according to claim 3,
wherein the land includes multiple lands disposed on the mounting surface, and a portion of the conductor connects between the multiple lands.

10. A circuit module comprising:
the electronic component package according to claim 2; and
a substrate on which the electronic component package is mounted.

11. A circuit module comprising:
the electronic component package according to claim 3; and
a substrate on which the electronic component package is mounted.

12. A circuit module comprising:
the electronic component package according to claim 4; and
a substrate on which the electronic component package is mounted.

13. A method of producing the electronic component package according to claim 2, the method comprising:
preparing a dummy substrate including a first surface on which a land is formed;
supplying solder to the dummy substrate so as to surround at least a portion of an outer circumference of the land;
mounting an electronic component to the dummy substrate by bringing the electronic component into contact with the solder;
sealing the electronic component with a sealing resin; and
removing the dummy substrate by grinding a second surface of the dummy substrate on which the land is not formed so as to expose the land and a conductor comprising solder or an alloy phase between the solder and another metal and surrounding at least a portion of an outer circumference of the land.

14. A method of producing the electronic component package according to claim 3, the method comprising:
preparing a dummy substrate including a first surface on which a land is formed;
supplying solder to the dummy substrate so as to surround at least a portion of an outer circumference of the land;
mounting an electronic component to the dummy substrate by bringing the electronic component into contact with the solder;
sealing the electronic component with a sealing resin; and
removing the dummy substrate by grinding a second surface of the dummy substrate on which the land is not formed so as to expose the land and a conductor comprising solder or an alloy phase between the solder and another metal and surrounding at least a portion of an outer circumference of the land.

15. A method of producing the electronic component package according to claim 4, the method comprising:
preparing a dummy substrate including a first surface on which a land is formed;
supplying solder to the dummy substrate so as to surround at least a portion of an outer circumference of the land;
mounting an electronic component to the dummy substrate by bringing the electronic component into contact with the solder;
sealing the electronic component with a sealing resin; and
removing the dummy substrate by grinding a second surface of the dummy substrate on which the land is not formed so as to expose the land and a conductor comprising solder or an alloy phase between the solder and another metal and surrounding at least a portion of an outer circumference of the land.
